(19) United States
(12) Patent Application Publication
(10) Pub. No.: US 2007/0257345 A1
(43) Pub. Date: Nov. 8, 2007

(54) Package structure to reduce warpage

(75) Inventors: Wen-Jeng Fan, Hukou (TW); Cheng-Pin Chen, Hukou (TW); Li-chih Fang, Hukou (TW)

Correspondence Address: BIRCH STEWART KOLASCH & BIRCH, PO BOX 747, FALLS CHURCH, VA, 22040-0747, US

(73) Assignee: Powertech Technology Inc.

(21) Appl. No.: 11/508,829

(22) Filed: Aug. 24, 2006

(30) Foreign Application Priority Data
May 2, 2006 (TW) 95115663

(51) Int. Cl. H01L 23/02

(52) U.S. Cl. 257/678

(57) ABSTRACT

A package structure includes: a substrate having a chip-bearing area arranged thereon; an window type assistant element arranged on the substrate and surrounding the edge of the chip-bearing area; a plurality of chips arranged within the chip-bearing area; and a package encapsulation covering chips within the chip-bearing area. It can resist the deformation and reduce the damage from the warpage and simultaneously enhance the yield and stability of the package structure.

### BACKGROUND OF THE INVENTION

1. Field of the Invention

The present invention relates to a package structure, particularly to a package structure to reduce warpage.

2. Description of the Prior Art

IC packaging process is a back-end process in the semiconductor industry and includes the following procedures: dicing, die attachment, wire bonding, encapsulation, printing, bumping, and singulation. The function of IC packaging is to provide an interface to transmit the internal IC signals to the external systems and enhance the strength of the IC chip and protect the IC chip from the corrosion and damage caused by water, moisture, chemical materials and external force.

In the encapsulation process, a mold is placed on a substrate having semiconductor chips or electronic elements, and an encapsulant is filled into the cavity of the mold, and then the mold is stripped away.

With the development of the thin package technology, the substrate becomes larger but thinner. The different kinds of packaging materials have different thermal expansion coefficients. The thermal stress, which is caused by the different extents of the dimensional variations occurring during temperature change, will induce the warpage of the package structure, and too great a warpage will crack the internal semiconductors or electronic elements. Therefore, how to solve the warpage problem of the encapsulation process is a focus in the field concerned.

### SUMMARY OF THE INVENTION

The primary objective of the present invention is to provide a package structure to reduce warpage and solve the abovementioned problems.

Another objective of the present invention is to provide a package structure, which can prevent the damage caused by warpage and promote the yield and stability of the package structure.

Further another objective of the present invention is to provide a package structure, which can reduce the warpage occurring during the molding process and PMC (Post Mold Cure) process.

To achieve the abovementioned objectives, one embodiment of the present invention proposes a package structure, which includes: a substrate having a chip-bearing area arranged thereon, a window type assistant element arranged on the substrate and surrounding around the edge of the chip-bearing area, a plurality of chips arranged within the chip-bearing area, and an encapsulant covering the chips within the chip-bearing area.

Another embodiment of the present invention proposes a package structure, which includes: a substrate having a plurality of chip-bearing areas arranged thereon, a plurality of window type assistant elements arranged on the substrate and respectively surrounding the edges of chip-bearing areas, a plurality of chips arranged within every chip-bearing area, and an encapsulant covering the chips on the chip-bearing areas.

### BRIEF DESCRIPTION OF THE DRAWINGS

FIG. 1 is a front view of the package structure according to one embodiment of the present invention;

FIG. 2 is a cross-sectional view along Line A-A in FIG. 1;

FIG. 3 is a front view of the package structure according to another embodiment of the present invention;

FIG. 4 is a cross-sectional view along Line B-B in FIG. 3;

FIG. 5 is a cross-sectional view of the package structure according to further another embodiment of the present invention; and

FIG. 6 is a partial front view of the package structure according to further another embodiment of the present invention.

### DESCRIPTION OF THE PREFERRED EMBODIMENT

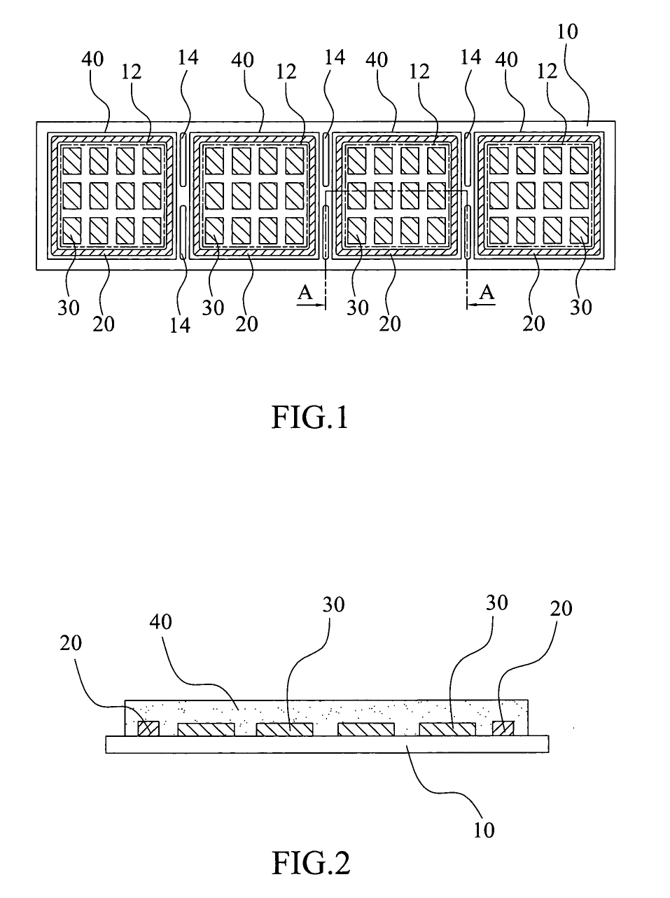

FIG. 1 is a front view of the package structure according to one embodiment of the present invention. In this embodiment, such as shown in FIG. 1, a plurality of chip-bearing areas 12 is arranged on a substrate 10, and a window type assistant element 20 surrounds the edge of each chip-bearing area 12; a plurality of chips 30 is arranged within every chip-bearing area 12, and the chips 30 are arranged in array; and an encapsulant 40 covers the chips 30 arranged on the chip-bearing areas 12.

FIG. 2 is a sectional view along Line A-A in FIG. 1. Referring to FIG. 2 and following the foregoing description, in addition to the chips 30 on the chip-bearing areas, the encapsulant 40 also covers the window type assistant element 20 in this embodiment. In the current fabrication method of the package structure, it generally includes the following steps: firstly, a substrate 10 is provide; next, chips 30 are stuck onto every chip-bearing area on the substrate 10; next, a wire-bonding procedure is undertaken to electrically connect the chips 30 and the substrate 10; next, a molding procedure is undertaken to cover the chips 30 on the chip-bearing areas with an encapsulant 40. The substrate 10 is made of at least one of the materials selected from the group consisting of polyimide, glass, alumina, epoxy, beryllium oxide and elastomer. The encapsulant 40 is mainly composed of EMC (Epoxy Molding Compound). The material used to stick the chips 30 (not shown in the drawings) onto the chip-bearing areas may be a silver paste, a chip-sticking film, or a nonconductive epoxy. After the molding procedure, a 0˜4 hour post mold cure procedure is usually needed to fully cure the encapsulant 40. In this embodiment, the window type assistant element 20 should adopt a heat-resistant material, such as a heat-resistant plastic, ceramic or metal. The heat-resistant material should be able to endure the fusion temperature of the encapsulant 40 and the temperature of the post mold cure procedure so that the window type assistant element 20 can protect the package structure against warpage. Besides, the window type assistant element 20 should also have the properties of high rigidity and high strength and have a low thermal expansion coefficient.

In the abovementioned embodiment, the substrate 10 has a plurality of opening trenches 14 for releasing the thermal stress induced by temperature change, as shown in FIG. 1. The window-type assistant element 20 is fixed to the substrate 10 with an adhesive (not shown in the drawings), and the window-type assistant element 20 is covered by the encapsulant 40 so that it can be more securely fixed to the substrate 10, as shown in FIG. 2. In the present invention, the window-type assistant element 20 may be installed to the substrate 10 before the chips 30 are stuck onto the substrate 10, or after the chips 30 have been stuck onto the substrate 10, or after the wire-bonding procedure has been undertaken. Thereby, the window-type assistant element 20 can be used to protect the package structure from the warpage occurring in various conditions, e.g. to prevent the warpage induced by the baking procedure after the chips 30 have been stuck onto the substrate 10, or by the fusion temperature of the encapsulant 40 in the molding procedure, or by the post mold cure procedure.

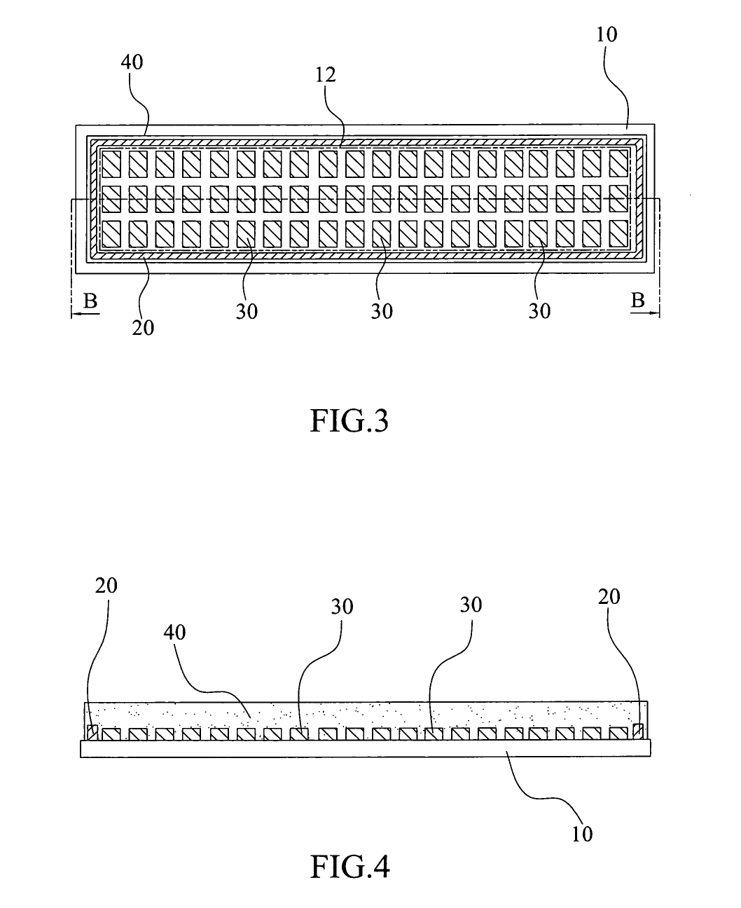

Refer to FIG. 3 a front view of the package structure according to another embodiment of the present invention. In this embodiment, a chip-bearing area 12 is arranged on a substrate 10, and a window type assistant element 20 surrounds the edge of the chip-bearing area 12; a plurality of chips 30 is arranged within the chip-bearing area 12; and an encapsulant 40 covers the chips 30 arranged within the chip-bearing area 12. The fabrication method of the package structure of the present invention has been described above and will not repeat here. Refer to FIG. 4 a sectional view along Line B-B in FIG. 3. As shown in FIG. 4, the window type assistant element 20, which surrounds the edge of the chip-bearing area 12, can effectively protect the package structure against the warpage induced by temperature change in the succeeding procedures. As all the chips 30 are arranged in array within a single chip-bearing area 12, the space of the substrate 10 can be fully utilized. Therefore, the substrate 10 can achieve the highest usage efficiency in this embodiment. Thus, the yield is promoted, and the cost is reduced.

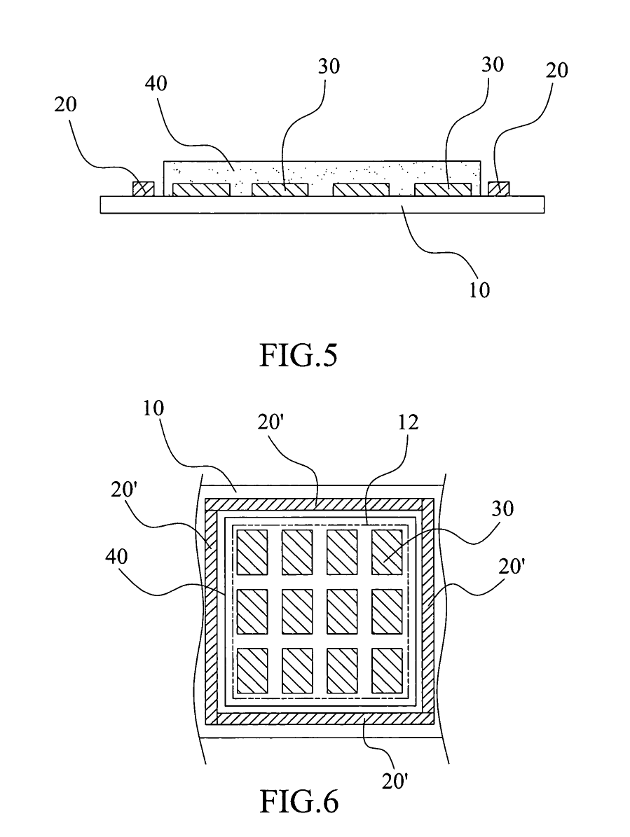

Refer to FIG. 5 and FIG. 6 respectively a sectional view and a partial front view of the package structure according to further another embodiment of the present invention. In this embodiment, the encapsulant 40 only covers the chips 30 arranged on the chip-bearing area 12. However, the window type assistant element, which is not covered by the encapsulant 40, can still protect the package structure against warpage. The window type assistant element should be made of a heat-resistant plastic, ceramic or metal. In this embodiment, the window type assistant element is formed of a plurality of strip-like elements 20′, such as plastic strips, metallic strips or ceramic strips.

The present invention is characterized in that at least one window type assistant element is installed around the edge of the chip-bearing area to enhance the strength of the substrate and prevent the package structure from being damaged by the warpage induced by temperature change. The window type assistant element may apply to any one of the package structures wherein chips are installed onto a substrate, such as the BGA (Ball Grid Array) package structure, the FBGA (Fine pitch Ball Grid Array) package structure, the VFBGA (Very Fine pitch Ball Grid Array) package structure, the BGA (micro Ball Grid Array) package structure and the wBGA (window Ball Grid Array) package structure. The window type assistant element may be either covered by the encapsulant or not covered by the encapsulant but surrounds the edge in the exterior of the encapsulant. The window type assistant element can effectively prevent the package structure from the warpage or deformation induced by temperature change during packaging process. Therefore, the window type assistant element can promote the yield and reduce the cost. In the succeeding singulation procedure, the window type assistant element will be cut off and abandoned. Thus, none extra structure exists in the final package structure.

In summary, the present invention discloses a package structure to reduce warpage, which can prevent a package structure from being damaged by the warpage occurring during packaging process and promote the yield and stability of the package structure.

Although the present invention has been explained in relation to its preferred embodiment, it is to be understood that other modifications and variations can be made without departing the spirit and scope of the invention as hereafter claimed.

What is claimed is:

1. A package structure, comprising:
a substrate having a chip-bearing area arranged thereon;
a window type assistant element arranged on said substrate and surrounding the edge of said chip-bearing area;
a plurality of chips arranged within said chip-bearing area; and
an encapsulant covering said chips within said chip-bearing area.

2. The package structure according to claim 1, wherein said substrate is made of at least one of the materials selected from the group consisting of polyimide, glass, alumina, epoxy, beryllium oxide and elastomer.

3. The package structure according to claim 1, wherein said window type assistant element is formed of any one of a plurality of metallic strips, a plurality of ceramic strips and a plurality of plastic strips.

4. The package structure according to claim 1, wherein said encapsulant is mainly composed of an epoxy molding compound.

5. The package structure according to claim 1, wherein said window type assistant element is covered within said encapsulant.

6. The package structure according to claim 1, wherein said window type assistant element is exposed and surrounding the edge of said encapsulant.

7. The package structure according to claim 1, wherein said chips are installed within said chip-bearing area of said substrate via one of the following technologies, comprising: the BGA (Ball Grid Array) package structure, the FBGA (Fine pitch Ball Grid Array) package structure, the VFBGA (Very Fine pitch Ball Grid Array) package structure, the BGA (micro Ball Grid Array) package structure, and the wBGA (window Ball Grid Array) package structure.

8. The package structure according to claim 1, which is fabricated with the following steps:
providing said substrate;
sticking said chips onto said chip-bearing area of said substrate;
electrically connecting said chips to said substrate; and
applying said encapsulant to cover said chips within said chip-bearing area.

9. The package structure according to claim 8, wherein before sticking said chips onto said chip-bearing area, said window type assistant element has been arranged on said substrate.

10. The package structure according to claim 8, wherein after said chips have been stuck onto said substrate, said window type assistant element is arranged on said substrate.

11. The package structure according to claim 8, wherein after said chips have been electrically connected to said substrate, said window type assistant element is arranged on said substrate.

12. A package structure, comprising:
a substrate having a plurality of chip-bearing areas arranged thereon;
a plurality of window type assistant elements arranged on said substrate and respectively surrounding the edges of said chip-bearing areas;
a plurality of chips arranged within every said chip-bearing area; and
an encapsulant covering said chips on said chip-bearing areas.

13. The package structure according to claim 12, wherein said substrate is made of at least one of the materials selected from the group consisting of polyimide, glass, alumina, epoxy, beryllium oxide and elastomer.

14. The package structure according to claim 12, wherein said window type assistant element is formed of any one of a plurality of metallic strips, a plurality of ceramic strips and a plurality of plastic strips.

15. The package structure according to claim 12, wherein said encapsulant is mainly composed of an epoxy molding compound.

16. The package structure according to claim 12, wherein said window type assistant element is covered within said encapsulant.

17. The package structure according to claim 12, wherein said window type assistant element is exposed and surrounding the edge of said encapsulant.

18. The package structure according to claim 12, further comprising a plurality of opening trenches formed on said substrate and arranged between said chip-bearing areas.

19. The package structure according to claim 12, wherein said chips are installed within every said chip-bearing area of said substrate via one of the following technologies, comprising: the BGA (Ball Grid Array) package structure, the FBGA (Fine pitch Ball Grid Array) package structure, the VFBGA (Very Fine pitch Ball Grid Array) package structure, the BGA (micro Ball Grid Array) package structure, and the wBGA (window Ball Grid Array) package structure.

20. The package structure according to claim 12, which is fabricated with the following steps:
providing said substrate;
sticking said chips onto every said chip-bearing areas;
electrically connecting said chips to said substrate; and
applying said encapsulant to cover said chips on said chip-bearing areas.

21. The package structure according to claim 20, wherein before sticking said chips onto said substrate, said window type assistant elements have been arranged on said substrate.

22. The package structure according to claim 20, wherein after said chips have been stuck onto said substrate, said window type assistant elements are arranged on said substrate.

23. The package structure according to claim 20, wherein after said chips have been electrically connected to said substrate, said window type assistant elements are arranged on said substrate.
